(19) United States
(12) Patent Application Publication
(10) Pub. No.: US 2024/0418786 A1
(43) Pub. Date: Dec. 19, 2024

(54) APPARATUS FOR MANAGING BATTERY AND METHOD THEREOF

(71) Applicants: HYUNDAI MOTOR COMPANY, Seoul (KR); Kia Corporation, Seoul (KR)

(72) Inventor: Uoon Hyuk BAEK, Hwaseong-si (KR)

(73) Assignees: HYUNDAI MOTOR COMPANY, Seoul (KR); Kia Corporation, Seoul (KR)

(21) Appl. No.: 18/386,681

(22) Filed: Nov. 3, 2023

(30) Foreign Application Priority Data
Jun. 13, 2023 (KR) 10-2023-0075607

(51) Int. Cl. G01R 31/388; B60L 58/18

(52) U.S. Cl. CPC G01R 31/388; B60L 58/18

(57) ABSTRACT

An apparatus for managing a battery and a method thereof includes a power converter that generates a second voltage by reducing a first voltage output from a power supply and output the second voltage, a first current sensor that detects a current of a first battery receiving the second voltage output from the power converter, and a second current sensor that detects a current of a second battery connected in series with the first battery.

### CROSS-REFERENCE TO RELATED APPLICATION

The present application claims priority to Korean Patent Application No. 10-2023-0075607, filed on Jun. 13, 2023, the entire contents of which is incorporated herein for all purposes by this reference.

### BACKGROUND OF THE PRESENT DISCLOSURE

### Field of the Present Disclosure

The present disclosure relates to an apparatus for managing a battery and a method thereof, and more particularly, to a technique for more efficiently managing a plurality of batteries.

### Description of Related Art

A vehicle is equipped with many electronic devices for driving the vehicle and providing safety and convenience of a driver. Devices in a vehicle, so-called electric devices, receive power from a generator or a fuel cell, or use a battery as a power source.

As the use of batteries expands, the importance of battery management has also increased. An apparatus for managing a battery manages a battery by estimating the state of charge (SOC) and the state of health (SOH) of the battery.

To estimate the SOC value and SOH of a battery, it is necessary to check the current of the battery. When one battery is used or two or more batteries having the same rated voltage are used, it is possible to accurately measure the current of a battery by use of one current sensor.

Recently, as electric devices of a vehicle increase, electric devices requiring different rated voltages are sometimes used. Accordingly, batteries having different nominal voltages may be provided in a vehicle to provide different voltages to electric devices.

Thus, it is difficult to measure current values for batteries having different voltage values by use of a single current sensor.

Furthermore, in a battery system currently used, even though a battery sensor is simply added, it is difficult to use a communication protocol between a battery sensor and a microcontroller unit (MCU).

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing an apparatus for managing a battery and a method thereof capable of more accurately measuring the SOC value of each of batteries including different rated voltages.

Furthermore, various exemplary embodiments of the present disclosure may prevent a situation in which communication is difficult in a process of transmitting a current value obtained by a current sensor.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, an apparatus for managing a battery includes a power converter that generates a second voltage by reducing a first voltage output from a power supply and output the second voltage, a first current sensor that detects a current of a first battery receiving the second voltage output from the power converter, and a second current sensor that detects a current of a second battery connected in series with the first battery.

According to an exemplary embodiment of the present disclosure, the power converter may receive the first voltage from the power supply implemented as a low voltage converter or an alternator.

According to an exemplary embodiment of the present disclosure, the first battery may be connected to a first load driven by the second voltage output from the power converter.

According to an exemplary embodiment of the present disclosure, the second battery may be connected to a second load driven by the first voltage output from the power supply.

According to an exemplary embodiment of the present disclosure, the first current sensor may be configured to determine a charging current or a discharging current of the first battery based on a voltage difference between a first electrode of the first battery and a ground.

According to an exemplary embodiment of the present disclosure, the first current sensor may include a first shunt resistor connected between the first electrode of the first battery and the ground, a first current interface which is configured for measuring the first voltage across the first shunt resistor, and a first current measurement device that is configured to determine the current of the first battery based on the first voltage.

According to an exemplary embodiment of the present disclosure, the ground may be connected to a ground of the vehicle.

According to an exemplary embodiment of the present disclosure, the ground may be connected to a ground of the power converter.

According to an exemplary embodiment of the present disclosure, the second current sensor may be configured to determine a charging current or a discharging current of the second battery based on a voltage difference between a first electrode of the second battery and a second electrode of the first battery.

According to an exemplary embodiment of the present disclosure, the second current sensor may include a second shunt resistor connected between the first electrode of the second battery and the second electrode of the first battery, a second current interface which is configured for measuring the second voltage across the second shunt resistor, and a second current measurement device that is configured to determine the current of the second battery based on the second voltage.

According to an exemplary embodiment of the present disclosure, the apparatus may further include a processor that estimates a state of charge (SOC) value of the first battery and an SOC value of the second battery based on the current of the first battery and the current of the second battery.

According to an exemplary embodiment of the present disclosure, the processor may be electrically connected to the current measurement device.

According to an exemplary embodiment of the present disclosure, the processor may estimate the SOC value of the first battery and the SOC value of the second battery based on ampere counting by use of the current of the first battery and the current of the second battery.

According to an exemplary embodiment of the present disclosure, the apparatus may further include a first voltage measurement device which is configured for measuring an open circuit voltage (OCV) of the first battery, and a second voltage measurement device which is configured for measuring an OCV of the second battery.

According to an exemplary embodiment of the present disclosure, the processor may estimate the SOC value of the first battery based on the OCV of the first battery and estimate the SOC value of the second battery based on the OCV of the second battery, based on an OCV-SOC relationship.

According to another aspect of the present disclosure, a method of managing a battery includes measuring, by a first current sensor, a first current of a first battery receiving a voltage output from a power converter, measuring, by a second current sensor, a second current of a second battery connected in series with the first battery, and estimating, by a processor, an SOC value of the first battery based on the first current and estimating an SOC value of the second battery based on the second current.

According to an exemplary embodiment of the present disclosure, the measuring of the first current may include measuring a charging current or a discharging current of the first battery receiving a second voltage output from the power convertor by reducing the first voltage supplied from a power supply to the second voltage.

According to an exemplary embodiment of the present disclosure, the measuring of the first current may include measuring the first current based on a voltage difference between a first electrode of the first battery and a ground.

According to an exemplary embodiment of the present disclosure, the measuring of the second current may include measuring a charging current or a discharging current of the second battery receiving the first voltage from a power supply.

According to an exemplary embodiment of the present disclosure, the estimating of the SOC value of the first battery and the SOC value of the second battery may include receiving, by the processor, a first current value of the first current and a second current value of the second current from the first current sensor and the second current sensor through a wire.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 and FIG. 2 are block diagrams illustrating the configuration of an apparatus for managing a battery according to an exemplary embodiment of the present disclosure;

FIG. 3 is a diagram illustrating a BEQ according to an exemplary embodiment of the present disclosure;

FIG. 4 is a diagram illustrating BEQ according to another exemplary embodiment of the present disclosure;

FIG. 5 is a flowchart illustrating a method of managing a battery according to an exemplary embodiment of the present disclosure;

FIG. 6 is a diagram illustrating a system for managing a battery according to a comparative example;

FIG. 7 is a diagram illustrating a system for managing a battery according to another comparative example; and

FIG. 8 is a diagram illustrating LIN communication between a second current sensor and an MCU.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, various exemplary embodiments of the present disclosure will be described in detail with reference to the exemplary drawings. In adding the reference numerals to the components of each drawing, it should be noted that the identical or equivalent component is designated by the identical numeral even when they are displayed on other drawings. Furthermore, in describing the exemplary embodiment of the present disclosure, a detailed description of the related known configuration or function will be omitted when it is determined that it interferes with the understanding of the exemplary embodiment of the present disclosure.

In describing the components of the exemplary embodiment of the present disclosure, terms such as first, second, A, B, (a), (b), and the like may be used. These terms are merely intended to distinguish the components from other components, and the terms do not limit the nature, order or sequence of the components. Unless otherwise defined, all terms including technical and scientific terms used herein include the same meaning as commonly understood by one of ordinary skill in the art to which the present disclosure belongs. It will be further understood that terms, such as those defined in commonly used dictionaries, should be interpreted as including a meaning which is consistent with their meaning in the context of the relevant art and will not be interpreted in an idealized or overly formal sense unless so defined herein.

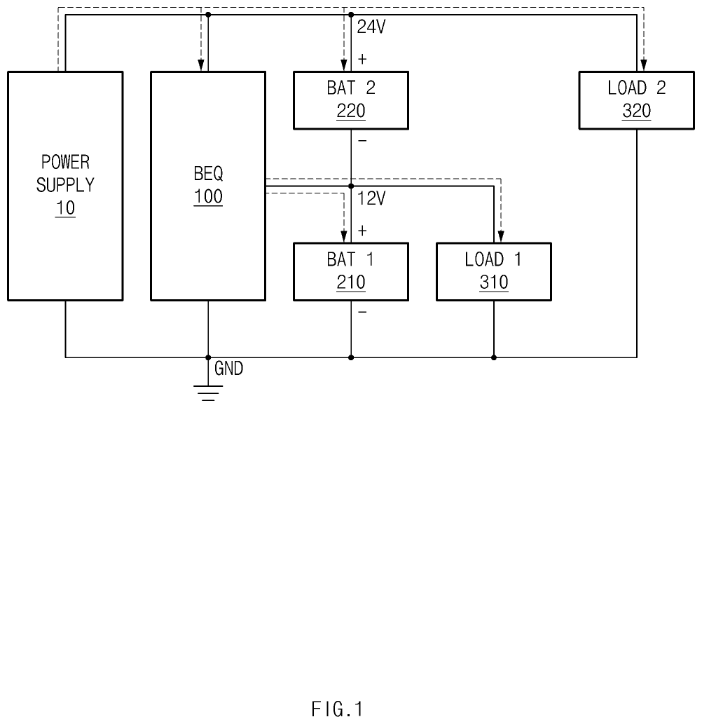

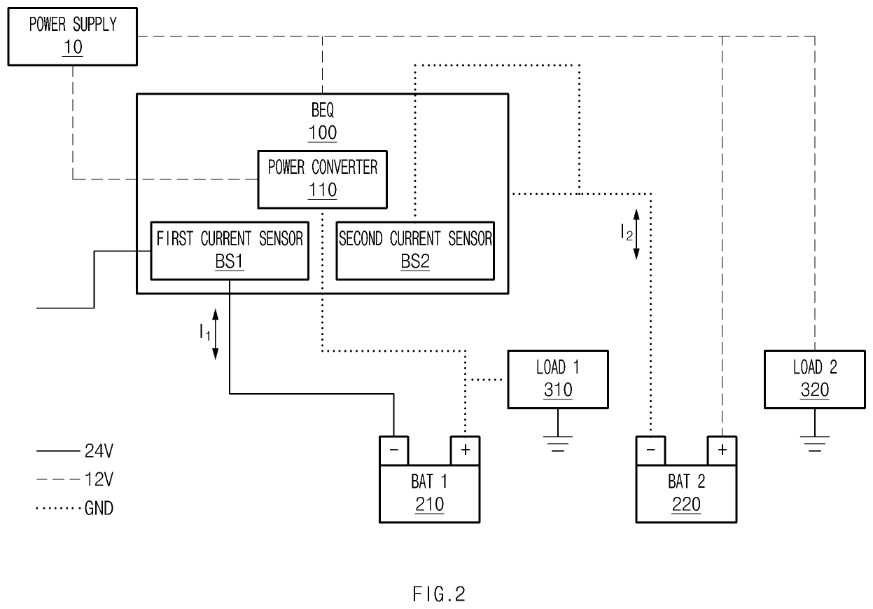

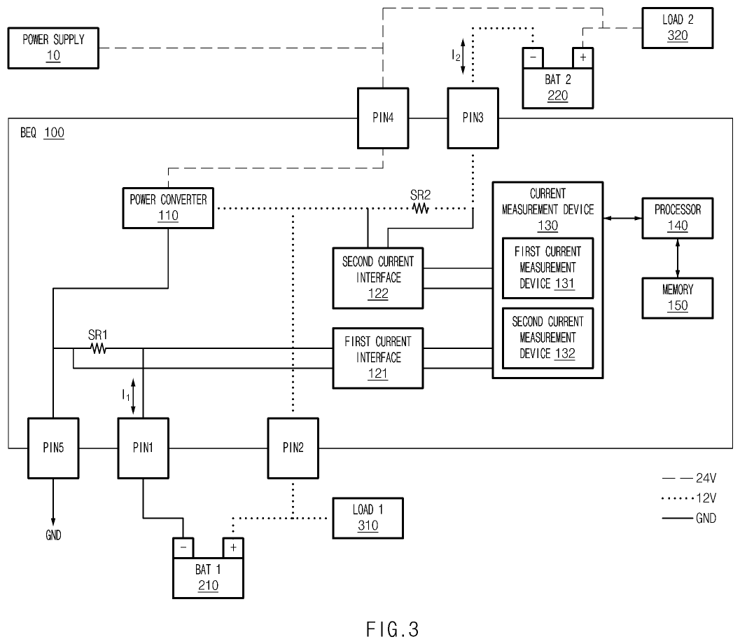

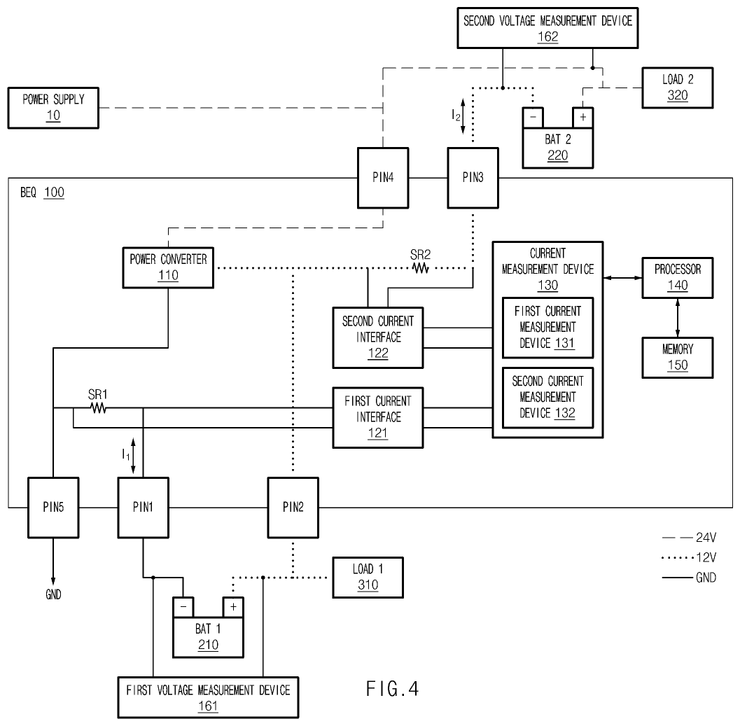

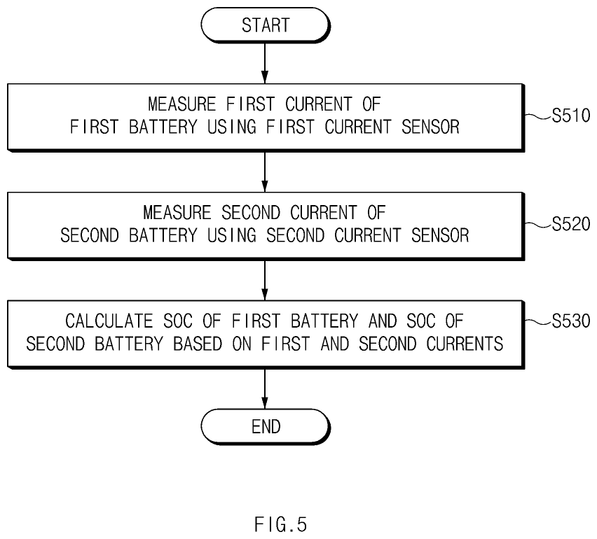

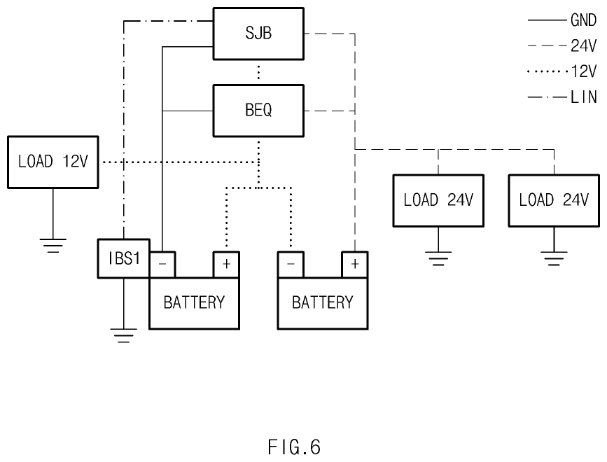

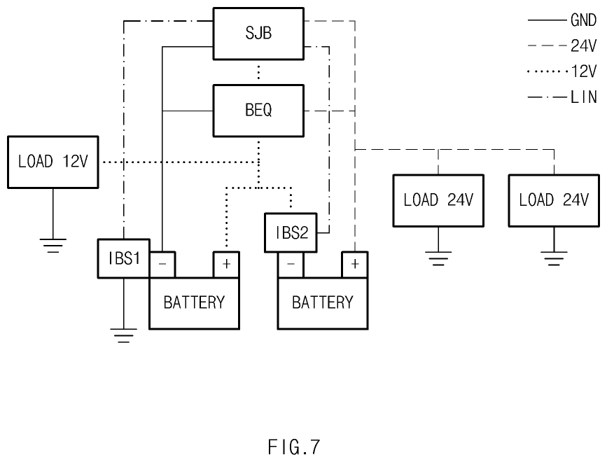

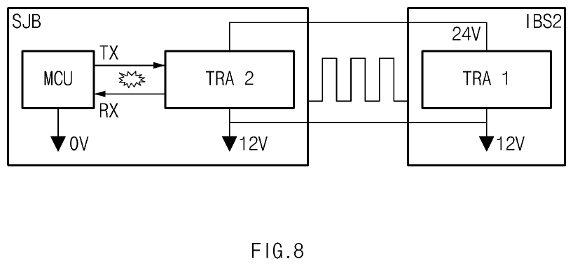

Hereinafter, various exemplary embodiments of the present disclosure will be described in detail with reference to FIG. 1, FIG. 2, FIG. 3, FIG. 4, FIG. 5, FIG. 6, FIG. 7, and FIG. 8.

FIG. 1 and FIG. 2 are block diagrams illustrating the configuration of an apparatus for managing a battery according to an exemplary embodiment of the present disclosure.

Referring to FIG. 1, an apparatus for managing a battery according to an exemplary embodiment of the present disclosure may be implemented as a battery equalizer (BEQ) 100 that reduces a voltage output from a power supply 10 and distributes it to a first battery 210 and a second battery 220. Hereinafter, an apparatus for managing a battery according to an exemplary embodiment of the present disclosure will be referred to as BEQ and described. The BEQ 100 according to an exemplary embodiment of the present disclosure may be mounted on a vehicle, provide a voltage for driving a first load 310, and charge batteries for driving the first load 310 and second loads 320.

At least one of the power supply 10 and the BEQ 100 may charge the first battery 210 and the second battery 220, and may provide a voltage for driving the first load 310 and the second load 320. The first load 310 and the second load 320 may be electrical components of a vehicle. The first load 310 may be devices including a rated voltage or nominal voltage of 12 V, and the second load 320 may be devices including a rated voltage or nominal voltage of 12 V.

The power supply 10 may output a first voltage to drive the second load 320 and to charge the second battery 220. The first voltage may be 24 V.

When the vehicle is an internal combustion engine vehicle, the power supply 10 may be an alternator. The alternator may be configured to generate electricity while the engine is operating and may output the first voltage.

When the vehicle is an eco-friendly vehicle such as an electric vehicle, the power supply 10 may be a low voltage DC-DC converter (LDC). The LDC may reduce a voltage output from a high voltage battery to output the first voltage.

The BEQ 100 may reduce the first voltage provided from the power supply 10 to output the second voltage. The second voltage may be 12V. The BEQ 100 may provide the second voltage to the first battery 210 and the first load 310.

Furthermore, the BEQ 100 may estimate a state of charge (SOC) value of the first battery 210 and an SOC value of the second battery 220. To the present end, the BEQ 100 may include a first current sensor BS1 and a second current sensor BS2.

The first current sensor BS1, which is provided to detect a current of the first battery 210, may measure the charging or discharging current of the first battery 210. The second current sensor BS2, which is used to detect the current of the second battery 220, may measure the charging or discharging current of the second battery 220. A detailed configuration of the BEQ 100 including the first current sensor BS1 and the second current sensor BS2 will be described below.

FIG. 3 is a diagram illustrating a BEQ according to an exemplary embodiment of the present disclosure.

Referring to FIG. 2 and FIG. 3, the BEQ 100 according to an exemplary embodiment of the present disclosure may include a power converter 110, the first current sensor BS1, the second current sensor BS2, a processor 140, and a memory 150.

The power converter 110 may receive the first voltage from the power supply 10 and reduce the first voltage to output the second voltage. Hereinafter, in an exemplary embodiment of the present disclosure, the first voltage will be referred to as 24V and the second voltage as 12V.

The power converter 110 may receive a voltage of 24 V from an output terminal of the power supply 10 through a fourth terminal Pin4. The fourth terminal Pin4 may be connected to a second electrode (+) of the second battery 220.

The power converter 110 may provide a voltage of 12 V to the first battery 210 and the first load 310 through a second terminal Pin2. The second terminal Pin2 may be connected to the first electrode (−) of the second battery 220, so that a second electrode (+) of the first battery 210 is connected to a first electrode (−) of the second battery 220.

The first current sensor BS1 may include a first shunt resistor SR1, a first current interface 121, and a first current measurement device 131.

The first shunt resistor SR1 may be connected to a fifth terminal Pin5 connected to a first terminal Pin1 of the first battery 210 and a ground GND. A potential proportional to a resistance value of the first shunt resistor SR1 may occur between both terminals of the first shunt resistor SR1 when the first battery 210 is charged or discharged.

The first current interface 121 may be connected to both terminals of the first shunt resistor SR1 to detect a potential across the first shunt resistor SR1. The first current interface 121 may convert the first voltage corresponding to a potential across the first shunt resistor SR1 into a digital signal and provide the converted digital signal to the first current measurement device 131.

The first current measurement device 131 may be configured to determine the current of the first shunt resistor SR1 based on digital data of the first voltage received from the first current interface 121. For example, the first current measurement device 131 may be configured to determine the first current flowing through the first shunt resistor SR1 using Ohm's law based on the resistance value and the first voltage of the first shunt resistor SR1. A current flowing through the first shunt resistor SR1 may be the same as a current of the first battery 210 while the first battery 210 is charged or discharged.

The second current sensor BS2 may include a second shunt resistor SR2, a second current interface 122, and a second current measurement device 132.

The second shunt resistor SR2 may be connected to a third terminal Pin3 and a second terminal Pin2. The third terminal Pin3 may be connected to the first electrode (−) of the second battery 220, and the second terminal Pin2 may be connected to the second electrode (+) of the first battery 210. The second terminal Pin2 may be connected to the ground of the BEQ 100. The ground of the BEQ 100 may be connected to the ground of the vehicle. A potential difference proportional to a resistance value of the second shunt resistor SR2 may occur across the second shunt resistor SR2 when the second battery 220 is charged or discharged.

The second current interface 122 may be connected to both terminals of the second shunt resistor SR2 to detect a potential across the second shunt resistor SR2. The second current interface 122 may convert the second voltage corresponding to the potential across the second shunt resistor SR2 into a digital signal and provide the converted digital signal to the second current measurement device 132.

The second current measurement device 132 may be configured to determine the current of the second shunt resistor SR2 based on the digital data of the second voltage provided from the second current interface 122. For example, the first current measurement device 131 may be configured to determine the first current flowing through the second shunt resistor SR2 by use of Ohm's law based on the resistance value of the second shunt resistor SR2 and the second voltage. A current flowing through the second shunt resistor SR2 may be the same as a current of the second battery 220 while the second battery 220 is charged or discharged.

The second current measurement device 132 and the first current measurement device 131 may be implemented as one integrated circuit.

The processor 140 may estimate the SOC value of the first battery 210 based on the first current of the first battery 210 provided from the first current measurement device 131, and may estimate the SOC value of the second battery 220 based on the second current of the second battery 220 provided from the second current measurement device 132. For example, the processor 140 may be configured to determine the SOC value of the first battery 210 by accumulating the first current based on ampere counting, and may be configured to determine the SOC value of the second battery 220 by accumulating the second current based on the ampere counting.

The processor 140 may be electrically connected to a current measurement device 130. Furthermore, the processor 140 may be implemented as an integrated circuit integrated with the current measurement device 130. Therefore, the processor 140 may not be required to use a communication protocol such as LIN communication or CAN communication to receive the first current value of the first battery 210 and the second current value of the second battery 220, and prevent a situation in which communication is difficult due to a ground deviation in a process of using the communication protocol. The details will be described later.

Furthermore, the processor 140 may be configured to determine a state of health (SOH) based on the first current value and the second current value.

Furthermore, the processor 140 may perform preset procedures based on SOC or SOH of the first battery 210 and the second battery 220.

The memory 150 may store an algorithm for operation of the processor 140. For example, the memory 150 may store an algorithm for SOC estimation. The memory 150 may include a hard disk drive, a flash memory, an electrically erasable programmable read-only memory (EEPROM), a static RAM (SRAM), a ferro-electric RAM (FRAM), a phase-change RAM (PRAM), a magnetic RAM (MRAM), a dynamic random access memory (DRAM), a synchronous dynamic random access memory (SDRAM), a double date rate-SDRAM (DDR-SDRAM), and the like.

Furthermore, although not shown in the drawings, the BEQ 100 may include a temperature sensor. The temperature sensor may include a first temperature sensor connected to the first electrode (−) of the first battery 210 and a second temperature sensor connected to the first electrode (−) of the second battery 220. The first temperature sensor may measure the temperature of the first battery 210 and the second temperature sensor may measure the temperature of the second battery 220.

The temperature of the first battery 210 and the temperature of the second battery 220 measured by the temperature sensor may be provided to the processor 140.

FIG. 4 is a diagram illustrating BEQ according to another exemplary embodiment of the present disclosure.

Referring to FIG. 4, the BEQ 100 according to another exemplary embodiment of the present disclosure may include the power converter 110, the first current sensor BS1, the second current sensor BS2, a first voltage measurement device 161, a second voltage measurement device 162, the processor 140, and the memory 150. Hereinafter, a detailed description of the same configuration as that shown in FIG. 3 described above in the description of FIG. 4 will be omitted.

The first voltage measurement device 161 may be connected to the first electrode (−) and the second electrode (+) of the first battery 210 to measure the open circuit voltage (OCV) of the first battery 210.

The second voltage measurement device 162 may be connected to the first electrode (−) and the second electrode (+) of the second battery 220 to measure the OCV of the second battery 220.

The memory 150 may store the OCV-SOC relationship in a form of a table, map, or function.

The processor 140 may estimate the SOC value of the first battery 210 and the SOC value of the second battery 220 based on the OCV-SOC relationship stored in the memory 150.

FIG. 5 is a flowchart illustrating a method of managing a battery according to an exemplary embodiment of the present disclosure.

Hereinafter, a method of controlling a battery according to an exemplary embodiment of the present disclosure will be described with reference to FIG. 1, FIG. 2, FIG. 3, FIG. 4, and FIG. 5.

In S510, the first current sensor BS1 may measure the first current of the first battery 210.

The first current sensor BS1 may measure the charging or discharging current of the first battery 210 that receives a voltage of 12 V output from the power converter 110. The first current sensor BS1 may measure the first current based on the voltage difference between the first electrode (−) of the first battery 210 and the ground GND. For example, a potential difference may occur across the first shunt resistor SR1 due to the current flow between the first electrode (−) and the ground GND. The first current interface 121 may obtain the voltage between both terminals of the first shunt resistor SR1 as the first voltage, convert the first voltage into a digital signal, and provide the converted digital signal to the first current measurement device 131. The first current measurement device 131 may be configured to determine the first current flowing through the first shunt resistor SR1 based on the magnitude of the first voltage, and may estimate the first current as the current of the first battery 210.

In S520, the second current sensor BS2 may measure the second current of the second battery 220.

The second current sensor BS2 may measure the charging or discharging current of the second battery 220 that receives a voltage of 24 V output from the power supply 10. The second current sensor BS2 may measure the first current based on the voltage difference between the first electrode (−) of the second battery 220 and the second electrode (+) of the first battery 210. For example, the potential may occur across the second shunt resistor SR2 due to the current flow between the first electrode (−) of the second battery 220 and the first electrode (−) of the first battery 210. The second current interface 122 may obtain a voltage of both terminals of the second shunt resistor SR2 as the second voltage, convert the second voltage into a digital signal, and provide the digital signal to the second current measurement device 132. The second current measurement device 132 may be configured to determine the second current flowing through the second shunt resistor SR2 based on the magnitude of the second voltage, and may estimate the second current as the current of the second battery 220.

In S530, the processor 140 may estimate the SOC value of the first battery 210 based on the first current and estimate the SOC value of the second battery 220 based on the second current.

The processor 140 may be configured to determine the SOC value of the first battery 210 and the SOC value of the second battery 220 based on an well-known algorithm for estimating an SOC stored in the memory 150.

Because the processor 140 is electrically connected to the current measurement device 130, there is no need to use a communication protocol to receive the current value of the first battery 210 and the current value of the second battery 220 from the current measurement device 130. Therefore, according to an exemplary embodiment of the present disclosure, it is possible to avoid a situation in which LIN communication is impossible due to the different grounds of the first current sensor BS1 and the second current sensor BS2. This will be described below with reference to FIGS. 6 to 8.

FIG. 6 is a diagram illustrating a system for managing a battery according to a comparative example.

Referring to FIG. 6, a battery current sensor IBS1 according to a comparative example may be configured separately from the BEQ and may detect the current of a first battery BAT1. The current sensor IBS1 may be connected to a first electrode (−) of the first battery BAT1 to measure the current of the first battery BAT1. The current sensor IBS1 may transmit the current value of the first battery BAT1 to a smart junction box (SJB) by use of LIN communication. The SJB may transmit the current value of the first battery BAT1 to an MCU which is not shown, and the MCU may estimate the SOC value of the first battery BAT1 based on the current value of the first battery BAT1. Because the BEQ can maintain charge amounts of the first battery BAT1 and a second battery BAT2 to be equal to each other, the MCU may estimate the SOC value of the second battery BAT2 based on the SOC value of the first battery BAT1.

However, because the electric device using the 12V voltage is driven by the voltage provided from the first battery BAT1, SOC deviation may occur due to the difference in discharge current between the first battery BAT1 and the second battery BAT2. Because the SOC deviation is not completely improved even when the voltage balancing of BEQ is taken into account, it is impossible to accurately determine the SOC value of the second battery BAT2.

To determine the SOC value of the second battery BAT2, a current sensor configured for detecting the current of the second battery BAT2 may be additionally required, and a system for managing a battery shown in FIG. 7 may be considered.

FIG. 7 is a diagram illustrating a system for managing a battery according to another comparative example.

Referring to FIG. 7, a system for managing a battery according to another comparative example may include the first current sensor IBS1 configured for measuring the current of the first battery BAT1 and a second current sensor IBS2 configured for measuring the current of the second battery BAT2.

The first current sensor IBS1 may be connected to the first electrode (−) of the first battery BAT1 to measure the current of the first battery BAT1. The first current sensor IBS1 may transmit the current value of the first battery BAT1 to the SJB by use of LIN communication, and the SJB may transmit the current value of the first battery BAT1 to an MCU through LIN communication.

The second current sensor IBS2 may be connected to the first electrode (−) of the second battery BAT2 to measure the current of the second battery BAT2. Furthermore, the LIN communication shown in FIG. 8 may be required to transmit the current value obtained by the second current sensor IBS2 to the MCU.

FIG. 8 is a diagram illustrating LIN communication between a second current sensor and an MCU.

Referring to FIG. 8, a first transceiver TRA1 of the second current sensor IBS2 shown in FIG. 7 may be connected to a second transceiver TRA2 of the SJB through LIN communication. Because the second current sensor IBS2 is connected to the second electrode (+) of the first battery BAT1, the ground of the first transceiver TRA1 and the second transceiver TRA2 may be the voltage of the second electrode (+) of the first battery BAT1.

However, like other devices, because the ground of the MCU is connected to the ground of the vehicle corresponding to 0 V, it may be impossible to perform LIN communication between the second transceiver TRA2 and the MCU.

To the contrary, in an apparatus for managing a battery according to an exemplary embodiment of the present disclosure, the current measurement device 130 that is configured to determine the battery current based on the voltage value and the processor 140 that is configured to determine the SOC based on the battery current may be implemented as one integrated circuit. Accordingly, the processor 140 may receive the battery current value without using a separate communication protocol.

According to the exemplary embodiments of the present disclosure, it is possible to accurately determine the SOC value of each battery based on detecting the current of each of the batteries including different rated voltages.

Furthermore, according to the exemplary embodiments of the present disclosure, a current sensor and a processor for determining an SOC may be integrated in a battery equalizer, improving a phenomenon in which communication is impossible in a process of providing the detected current value to controllers.

Furthermore, various effects that are directly or indirectly understood through the present disclosure may be provided.

Although exemplary embodiments of the present disclosure have been described for illustrative purposes, those skilled in the art will appreciate that various modifications, additions and substitutions are possible, without departing from the scope and spirit of the present disclosure.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In the present specification, unless stated otherwise, a singular expression includes a plural expression unless the context clearly indicates otherwise.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An apparatus for managing a battery, the apparatus comprising:
a power converter configured to generate a second voltage by reducing a first voltage output from a power supply and output the second voltage;
a first current sensor configured to detect a current of a first battery receiving the second voltage output from the power converter; and
a second current sensor configured to detect a current of a second battery connected in series with the first battery.

2. The apparatus of claim 1, wherein the power converter is configured to receive the first voltage from the power supply implemented as a low voltage converter or an alternator.

3. The apparatus of claim 1, wherein the first battery is connected to a first load driven by the second voltage output from the power converter.

4. The apparatus of claim 1, wherein the second battery is connected to a second load driven by the first voltage output from the power supply.

5. The apparatus of claim 1, wherein the first current sensor is configured to determine a charging current or a discharging current of the first battery based on a voltage difference between a first electrode of the first battery and a ground.

6. The apparatus of claim 5, wherein the first current sensor includes:
a first shunt resistor connected between the first electrode of the first battery and the ground;
a first current interface configured for measuring the first voltage across the first shunt resistor; and
a first current measurement device configured to determine the current of the first battery based on the first voltage.

7. The apparatus of claim 6, wherein the ground is connected to a ground of a vehicle.

8. The apparatus of claim 5, wherein the ground is connected to a ground of the power converter.

9. The apparatus of claim 1, wherein the second current sensor is configured to determine a charging current or a discharging current of the second battery based on a voltage difference between a first electrode of the second battery and a second electrode of the first battery.

10. The apparatus of claim 9, wherein the second current sensor includes:
a second shunt resistor connected between the first electrode of the second battery and the second electrode of the first battery;
a second current interface configured for measuring a second voltage across the second shunt resistor; and
a second current measurement device configured to determine the current of the second battery based on the second voltage.

11. The apparatus of claim 1, further including:
a processor configured for estimating a state of charge (SOC) value of the first battery and an SOC value of the second battery based on the current of the first battery and the current of the second battery.

12. The apparatus of claim 11, wherein the processor is electrically connected to a current measurement device.

13. The apparatus of claim 11, wherein the processor is further configured for estimating the SOC value of the first battery and the SOC value of the second battery based on ampere counting by use of the current of the first battery and the current of the second battery.

14. The apparatus of claim 11, further including:
a first voltage measurement device configured for measuring an open circuit voltage (OCV) of the first battery; and
a second voltage measurement device configured for measuring an OCV of the second battery.

15. The apparatus of claim 14, wherein the processor is further configured for estimating the SOC value of the first battery based on the OCV of the first battery and estimate the SOC value of the second battery based on the OCV of the second battery, based on an OCV-SOC relationship.

16. A method of managing a battery, the method comprising:
measuring, by a first current sensor, a first current of a first battery receiving a voltage output from a power converter;
measuring, by a second current sensor, a second current of a second battery connected in series with the first battery; and
estimating, by a processor, a state of charge (SOC) value of the first battery based on the first current and estimating an SOC value of the second battery based on the second current.

17. The method of claim 16, wherein the measuring of the first current includes:
measuring a charging current or a discharging current of the first battery receiving a second voltage output from the power converter by reducing a first voltage supplied from a power supply to the second voltage.

18. The method of claim 17, wherein the measuring of the first current includes:
measuring the first current based on a voltage difference between a first electrode of the first battery and a ground.

19. The method of claim 16, wherein the measuring of the second current includes:
measuring a charging current or a discharging current of the second battery receiving the first voltage from a power supply.

20. The method of claim 16, wherein the estimating of the SOC value of the first battery and the SOC value of the second battery includes:
receiving, by the processor, a first current value of the first current and a second current value of the second current from the first current sensor and the second current sensor through a wire.
